(19) United States
(12) Patent Application Publication
(10) Pub. No.: US 2008/0112207 A1
(43) Pub. Date: May 15, 2008

(54) Solid electrolyte memory device

(76) Inventor: Cay-Uwe Pinnow, Corbeil Essonnes (FR)

Correspondence Address: SLATER & MATSIL LLP, 17950 PRESTON ROAD, SUITE 1000, DALLAS, TX, 75252, US

(21) Appl. No.: 11/595,780

(22) Filed: Nov. 10, 2006

(51) Int. Cl. G11C 11/00

(52) U.S. Cl. 365/148

(57) ABSTRACT

A solid electrolyte memory device includes at least one solid electrolyte memory cell, each of which including a reactive electrode, an inert electrode, and solid electrolyte positioned between the reactive electrode and the inert electrode, and at least one charge storing unit storing an electric charge, the at least one charge storing unit being electrically connected to the at least one solid electrolyte memory cell such that tuning voltages resulting from the charge stored in the at least one charge storing unit are applied across the solid electrolyte of each solid electrolyte memory cell connected to the at least one charge storing unit.

### TECHNICAL FIELD

The present invention relates to a solid electrolyte memory device, a charge storing unit module, a method of tuning an erasing voltage threshold of a solid electrolyte memory cell, and a method of tuning a writing voltage threshold of a solid electrolyte memory cell.

### BACKGROUND

Solid electrolyte memory technology, for example conductive bridging random access memory (CBRAM) technology, is expected to become an important memory technology in the future. However, in order to be competitive with other existing memory technologies such as DRAM or FLASH, it is desirable to improve the reliability of solid electrolyte devices during operation.

### SUMMARY OF THE INVENTION

According to one embodiment of the present invention, a solid electrolyte memory device includes at least one solid electrolyte memory cell, each of which comprising a reactive electrode, an inert electrode, and solid electrolyte positioned between the reactive electrode and the inert electrode, and at least one charge storing unit storing an electric charge, the at least one charge storing unit being electrically connected to the at least one solid electrolyte memory cell such that tuning voltages resulting from the charge stored in the at least one charge storing unit are applied across the solid electrolyte of each solid electrolyte memory cell connected to the at least one charge storing unit.

### BRIEF DESCRIPTION OF THE DRAWINGS

For a more complete understanding of exemplary embodiments of the present invention and the advantages thereof, reference is now made to the following description taken in conjunction with the accompanying drawings, in which:

FIG. 1A shows a schematic cross-section of view of a CBRAM cell set to a first memory state;

FIG. 1B shows a schematic cross sectional view of a CBRAM cell set to a second memory state;

FIG. 2A shows a schematic drawing illustrating the relationship between a voltage applied across a CBRAM cell and the resulting current flowing through the CBRAM cell;

FIG. 2B shows a schematic drawing illustrating the relationship between a voltage applied across a CBRAM cell and the resulting current flowing through the CBRAM cell if the CBRAM cell is connected to a charge storing unit;

FIG. 3A shows a first example of how to integrate a CBRAM cell into a CBRAM cell array;

FIG. 3B shows a second example of how to integrate a CBRAM cell into a CBRAM cell array;

FIG. 3C shows a third example of how to integrate a CBRAM cell into a CBRAM cell array;

FIG. 4A shows a fist example of how to connect a charge storing unit to a CBRAM cell;

FIG. 4B shows a second example of how to connect a charge storing unit to a CBRAM cell;

FIG. 4C shows a third example of how to connect charge storing units to a CBRAM cell;

FIG. 5 shows an electric symbol of a conductive bridging charge cell;

FIG. 6A shows one embodiment of the CBRAM device according to the present invention;

FIG. 6B shows one embodiment of the CBRAM device according to the present invention;

FIG. 7A shows one embodiment of the CBRAM device according to the present invention;

FIG. 7B shows one embodiment of the CBRAM device according to the present invention;

FIG. 8A shows one embodiment of the CBRAM device according to the present invention;

FIG. 8B shows one embodiment of the CBRAM device according to the present invention;

FIG. 9A shows one embodiment of the CBRAM device according to the present invention;

FIG. 9B shows one embodiment of the CBRAM device according to the present invention;

FIG. 10A shows one embodiment of the CBRAM device according to the present invention;

FIG. 10B shows one embodiment of the CBRAM device according to the present invention;

FIG. 11A shows one embodiment of the CBRAM device according to the present invention;

FIG. 11B shows one embodiment of the CBRAM device according to the present invention;

FIG. 12 shows one embodiment of the CBRAM device according to the present invention;

FIG. 13 shows one embodiment of the CBRAM device according to the present invention; and

FIG. 14 shows one embodiment of the CBRAM device according to the present invention.

### DETAILED DESCRIPTION OF ILLUSTRATIVE EMBODIMENTS

According to one embodiment of the present invention, a solid electrolyte memory device includes at least one solid electrolyte memory cell, each of which comprising a reactive electrode, an inert electrode, and solid electrolyte positioned between the reactive electrode and the inert electrode, and at least one charge storing unit storing an electric charge, the at least one charge storing unit being electrically connected to the at least one solid electrolyte memory cell such that tuning voltages resulting from the charge stored in the at least one charge storing unit are applied across the solid electrolyte of each solid electrolyte memory cell connected to the at least one charge storing unit.

For sake of simplicity it is assumed in the following description that the solid electrolyte memory device is a CBRAM device. It is to be understood that all embodiments discussed below may also be applied to other types of solid electrolyte memory devices.

Usually, switching voltages have to exceed a switching voltage threshold in order to switch the CBRAM cells from a conductive state to a resistive state, or vice versa. According to one embodiment of the present invention, the switching voltage threshold of CBRAM cells is “manipulated” by a tuning voltage applied across the CBRAM cells (the tuning voltage is “biasing” the CBRAM cells). The tuning voltage is generated by the charge stored in one charge storing unit or in a plurality of charge storing units electrically connected to the CBRAM cell (in series or in parallel). Thus, fluctuations of material specific parameters or material inherent parameters having an influence on the switching voltage threshold can be compensated, thereby improving the reliability of the CBRAM device.

According to one embodiment of the present invention, the amount of charge stored within a charge storing unit is adjustable such that the resulting tuning voltage sets an erasing voltage threshold of CBRAM cells connected to the charge storing unit to a predetermined erasing voltage threshold value (the erasing voltage applied across the solid electrolyte has to exceed the erasing voltage threshold in order to erase conductive paths within the CBRAM cells).

According to one embodiment of the present invention, the amount of charge stored within a charge storing unit is adjustable such that the resulting tuning voltage sets a writing voltage threshold of CBRAM cells connected to the charge storing unit to a predetermined writing voltage threshold value (the writing voltage applied across the solid electrolyte has to exceed the writing voltage threshold in order to form conductive paths within the CBRAM cells).

According to one embodiment of the present invention, the writing voltage threshold is the same for each CBRAM cell. Alternatively, the writing voltage threshold differs from CBRAM cell to CBRAM cell. In the latter case, the writing voltage threshold may be individually adjusted for each CBRAM cell, i.e., the charge stored within the charge storing units differ from charge storing unit to charge storing unit. In a similar way, according to one embodiment of the present invention, the erasing voltage threshold is the same for each CBRAM cell. Alternatively, the erasing voltage threshold differs from CBRAM cell to CBRAM cell. In the latter case, the erasing voltage threshold may be individually adjusted for each CBRAM cell, i.e., the charge stored within the charge storing units differ from charge storing unit to charge storing unit.

According to one embodiment of the present invention, the amount of charge stored within a charge storing unit lies within a range extending from Q=1.602*10⁻¹⁹ As to 1*10⁻¹⁵ As. However, the present invention is not restricted thereto.

According to one embodiment of the present invention, each charge storing unit is either connected to the reactive electrode or the inert electrode of a CBRAM cell.

According to one embodiment of the present invention, at least one charge storing unit is serially connected into the sensing current path of a CBRAM cell. In other words, the charge storing unit forms a part of the sensing current path (the path along which a sensing current is routed when reading out the memory state of the CBRAM cell), i.e., the sensing current flows through the charge storing unit.

According to one embodiment of the present invention, at least one charge storing unit is connected in parallel to at least one CBRAM cell.

According to one embodiment of the present invention, at least one charge storing unit is connected to reactive electrodes of a plurality of CBRAM cells or to inert electrodes of a plurality of CBRAM cells. This means that one single charge storing unit simultaneously tunes the writing/erasing voltage threshold of a plurality of CBRAM cells.

According to one embodiment of the present invention, the sensing current path of at least one CBRAM cell includes two charge storing units, a first charge storing unit being connected into a part of the sensing current path connected to the reactive electrode of the CBRAM cell, and a second charge storing unit being connected into a part of the sensing current path connected to the inert electrode of the CBRAM cell, respectively. More generally, each CBRAM cell may be connected to a plurality of charge storing units.

According to one embodiment of the present invention, the amount of charge stored within a charge storing unit is adjustable by applying a charge storing unit programming voltage across the charge storing unit.

According to one embodiment of the present invention, the charge storing unit programming voltage necessary for adjusting the amount of charge is higher than the writing voltage or the erasing voltage necessary for forming or erasing conductive paths within the CBRAM cells.

According to one embodiment of the present invention, at least one charge storing unit includes a current path input terminal and a current path output terminal, the amount of charge of each charge storing unit being adjustable by applying a programming voltage across the charge storing unit using the current path input terminal and the current path output terminal as programming voltage terminals. In other words, the current path input terminal and the current path output terminal are both used for routing the sensing currents through the charge storing unit and for programming the charge storing unit.

According to one embodiment of the present invention, at least one charge storing unit is arranged such that the tuning voltage generated by the charge storing unit is directly proportional to the charge stored within the charge storing unit.

According to one embodiment of the present invention, the charge stored within a charge storing unit is adjustable during a power up process, a power down process, or an idle mode of the CBRAM device or a part thereof.

According to one embodiment of the present invention, the amount of charge stored within a charge storing unit is adjustable during a memory operation performed within the CBRAM device.

According to one embodiment of the present invention, the amount of charge stored within a charge storing unit is adjustable during a manufacturing process of the CBRAM device.

According to one embodiment of the present invention, the CBRAM device includes controlling means controlling the charge amount adjustment process. Alternatively, external controlling means (for example, removably attachable (attachable and detachable) to the CBRAM device) may be used. For example, the CBRAM device may include a charge adjustment interface connectable to an external controlling means, the amount of charge adjustment process being controllable by the external controlling means via the charge adjustment interface.

According to one embodiment of the present invention, at least one charge storing unit is a charge trapping unit. According to one embodiment of the present invention, the charge storing units include dielectric material, semiconducting material, metallic material, or a combination of these materials.

According to one embodiment of the present invention, a charge storing unit is a device in which electrons or holes are permanently stored, e.g., a charge trapping unit, a floating gate structure or an interface (e.g., a metal-semiconductor interface, a semiconductor-insulator interface, a metal-insulator interface or a semiconductor-semiconductor interface). However, according to one embodiment of the present invention, a charge storing unit may also be a single capacitor or a plurality of capacitors having a volatile storage behavior (like that of dynamic random access memory (DRAM) devices). In order to maintain the amount of charge stored within the capacitors, the capacitors have to be recharged in certain time intervals. According to one embodiment of the present invention, a charge trapping unit is a dielectric or semiconductor layer on/in which electrons or holes are permanently stored.

According to one embodiment of the present invention, the charge storing units are non volatile charge storing elements storing electrons or holes for a long period of time.

According to one embodiment of the present invention, the charge storing units are charged by trapping or storing electrons or holes.

According to one embodiment of the present invention, a charge storing unit module including at least one charge storing unit storing an electric charge is provided, the at least one charge storing unit being electrically connectable to at least one solid electrolyte memory cell of a solid electrolyte memory device such that tuning voltages resulting from the stored charge are applied across the solid electrolyte of each solid electrolyte memory cell connected to the at least one charge storing unit.

For sake of simplicity it is assumed in the following description that the memory cells of the charge storing unit are CBRAM cells. It is to be understood that all embodiments discussed below may also be applied to other types of memory cells.

According to one embodiment of the present invention, the amount of charge stored within a charge storing unit is adjustable such that the resulting tuning voltage sets an erasing voltage threshold of CBRAM cells connected to the charge storing unit to a predetermined erasing voltage threshold value.

According to one embodiment of the present invention, the amount of charge stored within a charge storing unit is adjustable such that the resulting tuning voltage sets a writing voltage threshold of CBRAM cells connected to the charge storing unit to a predetermined writing voltage threshold value.

According to one embodiment of the present invention, the amount of charge stored within a charge storing unit lies within a range extending from Q=1.602*10⁻¹⁹ As to 1*10⁻¹⁵ As.

According to one embodiment of the present invention, the charge storing units are electrically connectable to the CBRAM cells via an interface being part of the charge storing unit module or the CBRAM device, the interface having defined charge storing and/or trapping properties.

Generally, all CBRAM cell embodiments discussed above are, if possible, also applicable to the charge storing unit module embodiments according to the present invention.

According to one embodiment of the present invention, a method of tuning an erasing voltage threshold of a solid electrolyte memory cell being electrically connected to at least one charge storing unit is provided, including the process of adjusting the charge stored within the at least one charge storing unit such that a tuning voltage resulting from the stored charge is applied across the solid electrolyte of the solid electrolyte memory cell, wherein the amount of charge stored is adjusted such that the tuning voltage tunes an erasing voltage threshold of the solid electrolyte memory cell to a predetermined erasing voltage threshold value.

According to one embodiment of the present invention, a method of tuning a writing voltage threshold of a solid electrolyte memory cell being electrically connected to at least one charge storing unit is provided, comprising the process of adjusting the charge stored within the at least one charge storing unit such that a tuning voltage resulting from the stored charge is applied across the solid electrolyte of the solid electrolyte memory cell, wherein the amount of charge stored is adjusted such that the tuning voltage tunes a writing voltage threshold of the solid electrolyte memory cell to a predetermined writing voltage threshold value.

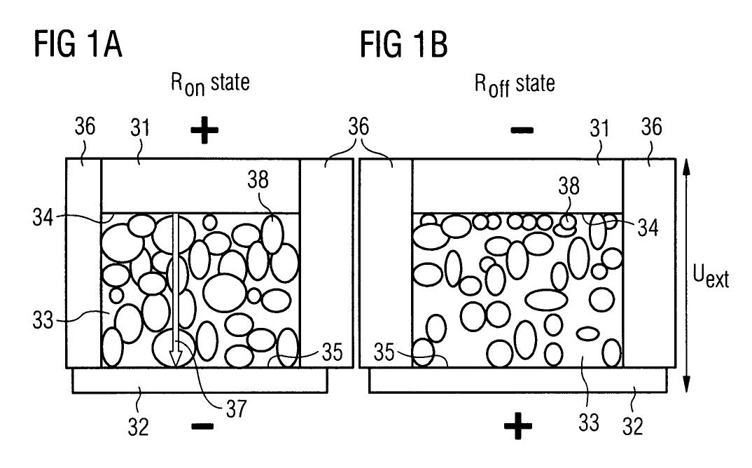

In the following description, making reference to FIGS. 1A and 1B, a basic principle underlying one embodiment of a conductive bridging unit (in the following also referred to as CBRAM cell) will be explained.

As shown in FIG. 1A, a CBRAM cell includes a first electrode 31, a second electrode 32, and a solid electrolyte block 33 sandwiched between the first electrode 31 and the second electrode 32. The first electrode 31 contacts a first surface 34 of the solid electrolyte block 33, the second electrode 32 contacts a second surface 35 of the solid electrolyte block 33. The solid electrolyte block 33 is isolated against its environment by an isolation structure 36. The first surface 34 usually is the top surface, the second surface 35 the bottom surface of the solid electrolyte 33. In the same way, the first electrode 31 generally is the top electrode, and the second electrode 32 the bottom electrode of the CBRAM cell. One of the first electrode 31 and the second electrode 32 is a reactive electrode, the other one an inert electrode. Here, the first electrode 31 is the reactive electrode, and the second electrode 32 is the inert electrode. In this example, the first electrode 31 includes silver (Ag), the solid electrolyte block 33 includes silver-doped chalcogenide material, and the isolation structure 36 includes silicon oxide (SiO₂). However, the invention is not restricted to these examples of material.

If a voltage as indicated in FIG. 1A is applied across the solid electrolyte block 33, a redox reaction is initiated that drives Ag⁺ ions out of the first electrode 31 into the solid electrolyte block 33 where they are reduced to Ag, thereby forming Ag rich clusters within the solid electrolyte block 33. If the voltage applied across the solid electrolyte block 33 is applied for a long period of time, the size and the number of Ag rich clusters within the solid electrolyte block 33 is increased to such an extent that a conductive bridge 37 between the first electrode 31 and the second electrode 32 is formed. In case that a voltage is applied across the solid electrolyte block 33 as shown in FIG. 1B (inverse voltage compared to the voltage applied in FIG. 1A), a redox reaction is initiated that drives Ag⁺ ions out of the solid electrolyte block 33 into the first electrode 31 where they are reduced to Ag. As a consequence, the size and the number of Ag rich clusters within the solid electrolyte block 33 is reduced, thereby erasing the conductive bridge 37.

In order to determine the current memory status of a CBRAM cell, a sensing current is routed through the CBRAM cell. The sensing current experiences a high resistance in case no conductive bridge 37 exists within the CBRAM cell, and experiences a low resistance in case a conductive bridge 37 exists within the CBRAM cell. A high resistance may, for example, represent “0,” whereas a low resistance represents “1,” or vice versa.

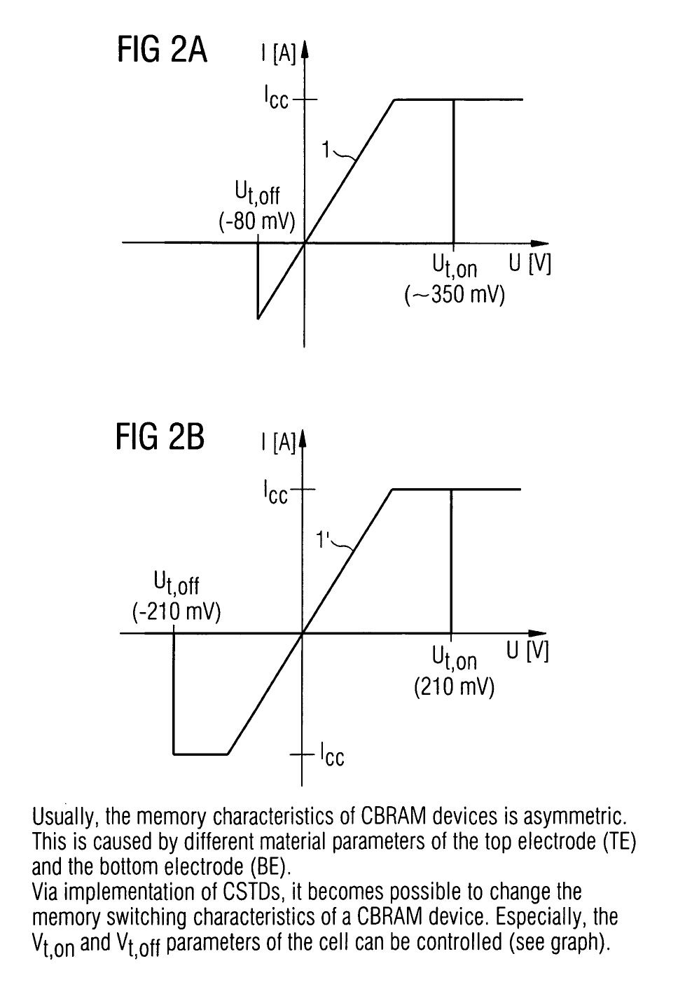

FIG. 2A shows the memory characteristics of a conventional CBRAM cell. As can be derived from FIG. 2A, the voltage threshold value for forming a conductive path within the solid electrolyte is about 350 mV, and the voltage threshold value for erasing a conductive path within the solid electrolyte is about −80 mV. As a consequence, the current curve is asymmetric with respect to the origin. The asymmetric current curve results from different materials that are used for the reactive electrode and the inert electrode of the CBRAM cell. One disadvantage of the asymmetric current curve is that two different voltage threshold values for forming and erasing conductive paths within the solid electrolyte have to be taken into account.

According to one embodiment of the present invention, it is possible to change the memory switching characteristics of a CBRAM cell in an arbitrary way, for example, by using the same voltage threshold value for both forming and erasing conductive paths within the solid electrolyte (only the sign of the voltage is inversed). If the voltage thresholds for erasing and forming conductive paths are the same, a symmetric current curve is obtained, as shown in FIG. 2B.

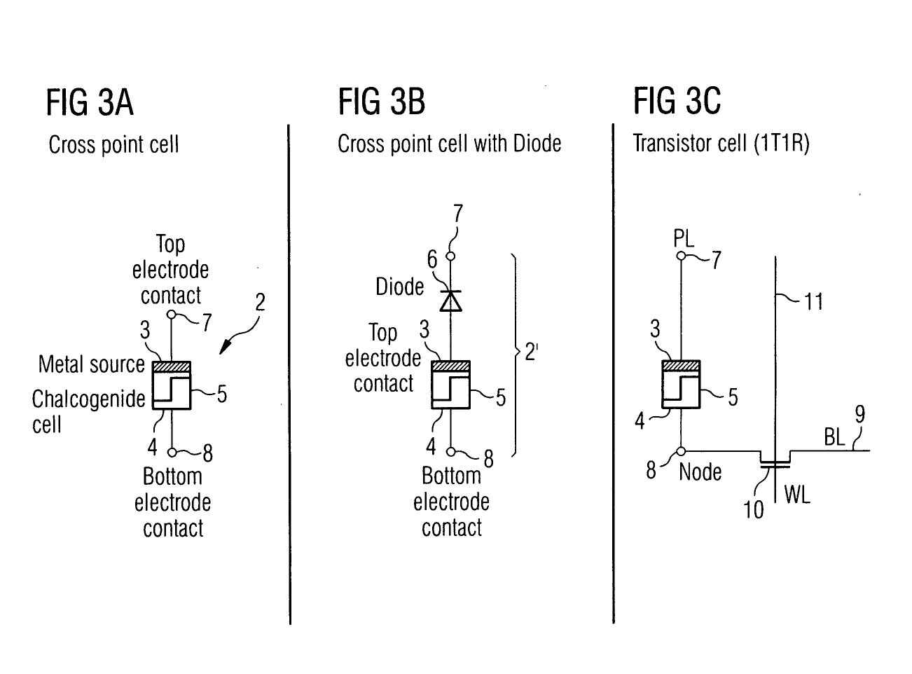

FIG. 3A shows a CBRAM cell 2 including a reactive electrode 3, an inert electrode 4, and a solid electrolyte 5 positioned between the reactive electrode 3 and the inert electrode 4. The CBRAM cell 2 is used in CBRAM cell arrays having a plurality of word lines and bit lines. Several types of CBRAM cell array architectures exist. In the crosspoint architecture, the CBRAM cells 2 connect the word lines to the bit lines within word line/bit line intersection areas (i.e., a first CBRAM cell terminal 7 connected to the reactive electrode 3 is connected to a bit line, a second CBRAM cell terminal 8 connected to the inert electrode 4 is connected to a word line of a CBRAM cell array, or vice versa). FIG. 3B shows a CBRAM cell 2′ which, compared to the CBRAM cell 2 shown in FIG. 3A, additionally includes a diode 6 connected to the reactive electrode 3. The purpose of the diode 6 is to avoid cross talk between neighboring CBRAM cells. The CBRAM cell 21 is integrated into a CBRAM cell array in the same way as the CBRAM cell 2, i.e., a first CBRAM cell terminal 7 is connected to a bit line of a CBRAM cell array, a second CBRAM cell terminal 8 is connected to a word line of a CBRAM cell array, or vice versa (“cross point cell architecture”). FIG. 3C shows a CBRAM cell which is identical to the CBRAM cell 2 shown in FIG. 3A; however, the way the CBRAM cell is integrated into the CBRAM cell array is different: The first CBRAM cell terminal 7 is connected to a line or connection set to a fixed potential, for example, mass potential. The second CBRAM cell terminal 8 is connected to a bit line 9 via a select device 10. The select device 10 (for example, a transistor) is controlled by a word line 11 (“transistor cell architecture”).

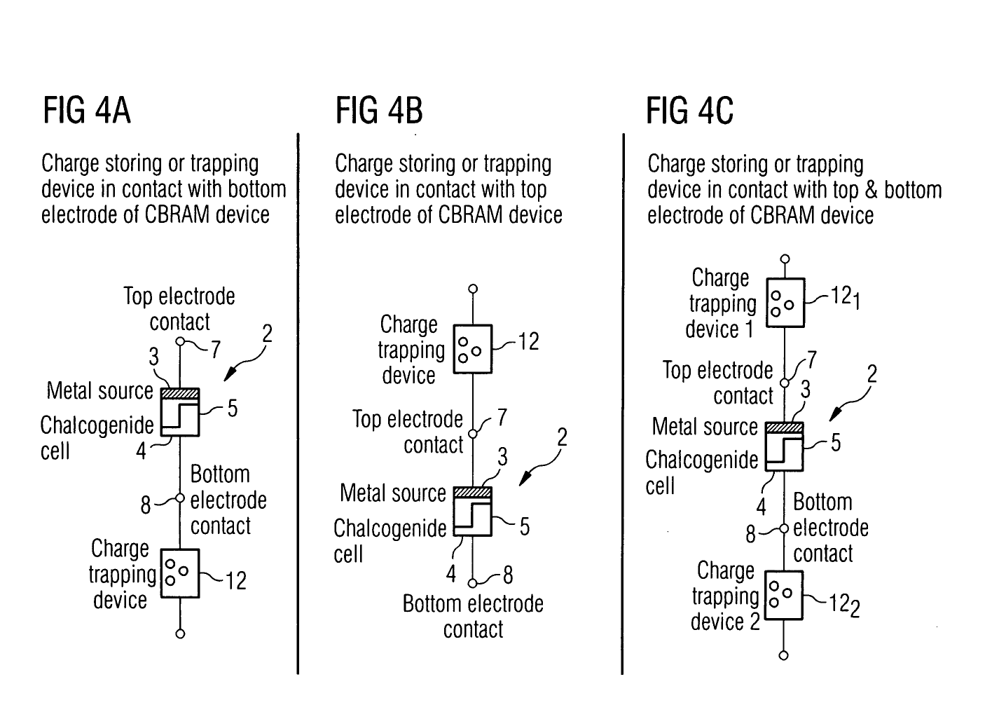

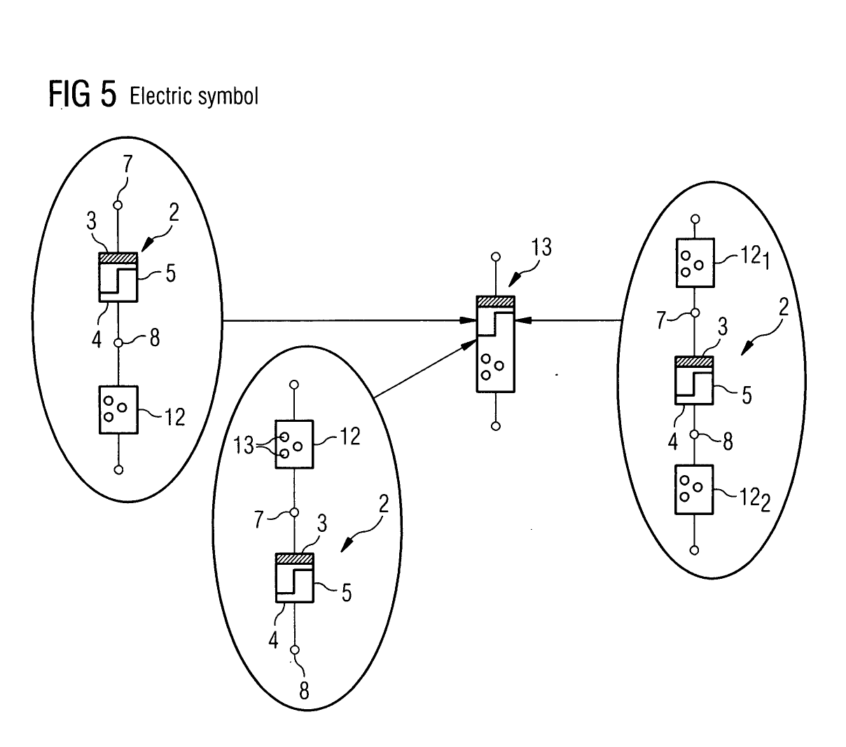

FIG. 4A shows a first example of how a charge storing unit may be connected to the CBRAM cell 2 shown in FIG. 3A. In this example, the charge storing unit 12 is connected to the inert electrode 4 of the CBRAM cell 2. FIG. 4B shows the case where the charge storing unit 12 is connected to the reactive electrode 3 of the CBRAM cell 2. FIG. 4C shows the embodiment in which a first charge storing unit 121 is connected to the reactive electrode 3 of the CBRAM cell 2, and a second charge storing unit 122 is connected to the inert electrode 4 of the CBRAM cell 2. FIG. 5 shows an electric symbol 13 including all examples shown in FIGS. 4A to 4C. The electric symbol 13 may be referred to as a “conductive bridging charge cell” since its behavior depends on the charge stored within the charge storing units 12. The charge storing units 12 may be connected to the CBRAM cells 2, i.e., represent a separate unit, or be directly integrated into the CBRAM cells 2, i.e., the CBRAM cell 2 and the charge storing unit(s) together form a single unit (“conductive bridging charge cell”).

The charge storing units 12 can be connected in a similar way to the CBRAM cells 2′, 2″ shown in FIGS. 3B and 3C.

The amount of charge 13 stored or trapped within the charge storing units 12 is adjustable such that a tuning voltage resulting form the stored charge 13 adjusts an erasing voltage threshold of the CBRAM cells 2 connected to the charge storing units 12 to a predetermined erasing voltage threshold value, which has to be exceeded by an erasing voltage applied across the solid electrolytes 5 in order to erase conductive paths within the CBRAM cells 2.

Alternatively or additionally, the amount of charge 13 stored or trapped within each charge storing unit 12 is adjustable such that a resulting tuning voltage adjusts a writing voltage threshold of the CBRAM cells 2 connected to the charge storing unit 12 to a predetermined writing voltage threshold value, which has to be exceeded by a writing voltage applied across the solid electrolytes 5 in order to form conductive paths within the CBRAM cells 2.

According to one embodiment of the present invention, the amount of charge 13 stored within a charge storing unit 12 lies within a range extending from Q=1,602×10⁻¹⁹ As to 1×10⁻¹⁰ As.

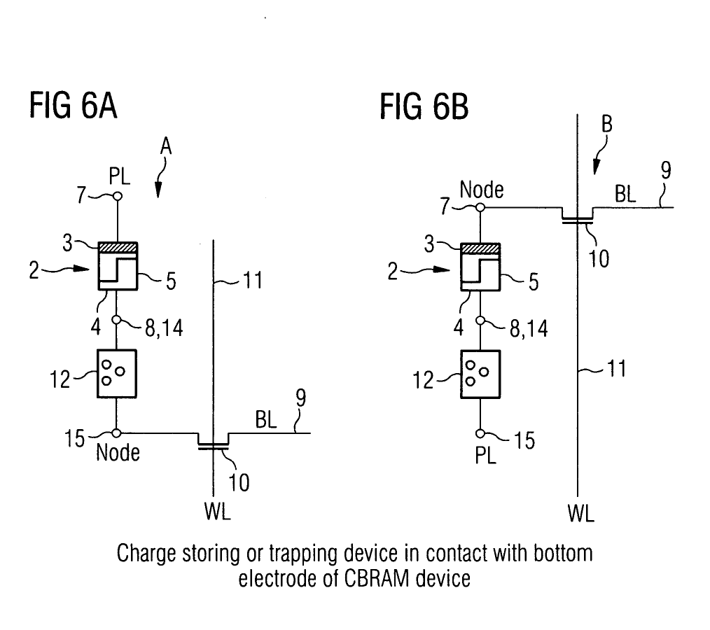

FIG. 6A shows an embodiment A of a CBRAM device according to the present invention. The embodiment A includes a CBRAM cell 2, a charge storing unit 12, and a select device 10. The CBRAM cell 2 includes a reactive electrode 3, an inert electrode 4, and a solid electrolyte 5 positioned between the inert electrode 4 and the reactive electrode 3. The CBRAM cell 2 includes a first CBRAM cell terminal 7 and a second CBRAM cell terminal 8. The first CBRAM cell terminal 7 is connected to the reactive electrode 3 of the CBRAM cell 2, the second CBRAM cell terminal 8 is connected to the inert electrode 4 of the CBRAM cell 2. The first CBRAM cell terminal 7 is further connected to an area set to a fixed potential (PL), the second CBRAM cell terminal 8 is further connected to a first charge storing unit terminal 14 of a charge storing unit 12. A second charge storing unit terminal 15 is connected to a bit line 9 via the select device 10. The select device 10 is controlled by a word line 11.

FIG. 6B shows an embodiment B of the CBRAM device according to the present invention having the same architecture as that of embodiment A. However, the first CBRAM cell terminal 7 now is connected to a bit line 9 via the select device 10, the select device 10 being controlled by a word line 11, and the second charge storing unit terminal 15 now is connected to an area set to a fixed potential (PL).

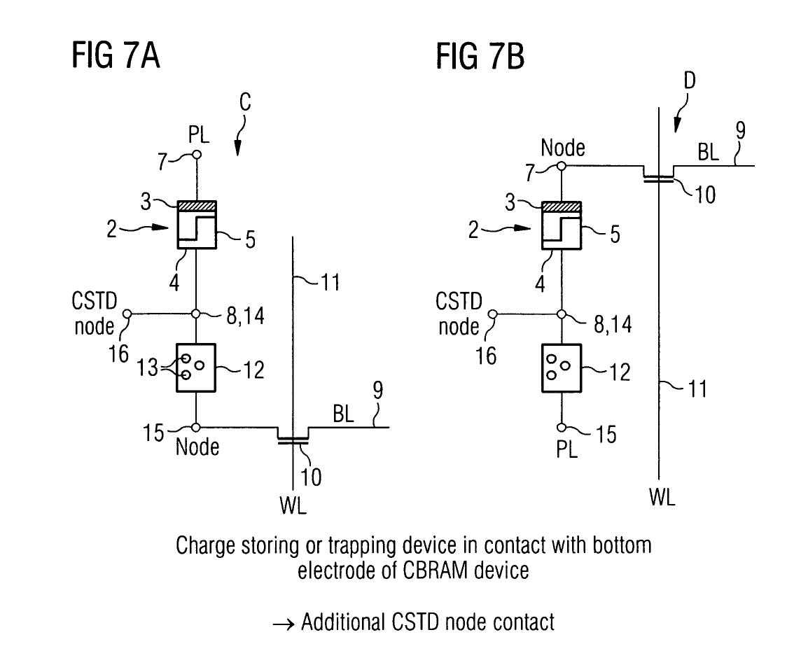

FIG. 7A shows an embodiment C of a CBRAM device according to the present invention having the same arrangement as the embodiment A show in FIG. 6A. In addition, a first additional charge storing unit terminal 16 is connected to the first charge storing unit terminal 14. The first additional charge storing unit terminal 16 may, for example, be used together with the second charge storing unit terminal 15 to adjust the amount of charge 13 stored within the charge storing unit 12 by applying a charge storing unit programming voltage across the charge storing unit 12 using the first additional charge storing unit terminal 16 and the second charge storing unit terminal 15 as voltage suppliers. Thus, it is possible to adjust the charge stored/trapped within the charge storing unit 12 even after the fabrication process of the CBRAM device has been finished, for example, during the operation of CBRAM device.

FIG. 7B shows an embodiment D of the CBRAM device according to the present invention. The embodiment D has the same architecture as the embodiment B shown in FIG. 6B except a first additional charge storing unit terminal 16 is connected to the first charge storing unit terminal 14. The purpose of the first additional charge storing unit terminal 16 is the same as that of embodiment C shown in FIG. 7A.

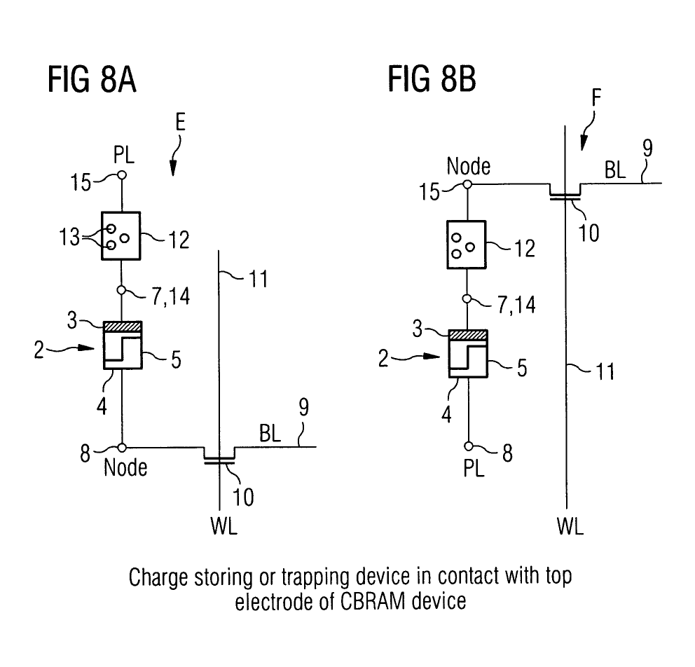

FIG. 8A shows an embodiment E of a CBRAM device according the present invention. The embodiment E includes a charge storing unit 12, a CBRAM cell 2 and a select device 10. The CBRAM cell 2 includes a reactive electrode 3, an inert electrode 4 and a solid electrolyte 5 positioned between the inert electrode 4 and the reactive electrode 3. The CBRAM cell 2 includes a first CBRAM cell terminal 7 and a second CBRAM cell terminal 8. The first CBRAM cell terminal 7 is connected to the reactive electrode 3 of the CBRAM cell 2, the second CBRAM cell terminal 8 is connected to the inert electrode 4 of the CBRAM cell 2. The first CBRAM cell terminal 7 is further connected to a first charge storing unit terminal 14 of a charge storing unit 12. A second charge storing unit terminal 15 is connected to an area set to a fixed potential (PL), for example, mass potential. The second CBRAM cell terminal 8 is further connected to a bit line 9 via the select device 10. The select device 10 is controlled by a word line 11.

FIG. 8B shows an embodiment F of the CBRAM device according to the present invention having the same architecture as that of embodiment E. However, now the second CBRAM cell terminal 8 is connected to an area set to a fixed potential (for example, mass potential), and the second charge storing unit terminal 15 is connected to a bit line 9 via the select device 10 (which is controlled by the word line 11).

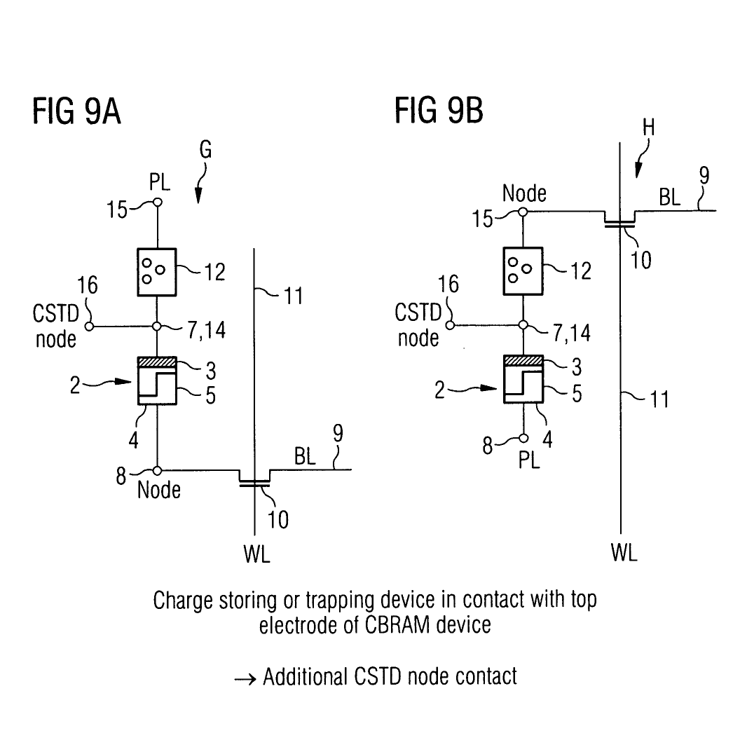

FIG. 9A shows an embodiment G of the CBRAM device according to the present invention. The embodiment G has the same architecture as that of embodiment E shown in FIG. 8A, except that a first additional charge storing unit terminal 16 is provided, which contacts the first charge storing unit terminal 14. The purpose of the first additional charge storing unit terminal 16 is the same as that of embodiment D shown in FIG. 7B.

FIG. 9B shows an embodiment H of the CBRAM device according to the present invention. The embodiment H has the same architecture as that of embodiment F in FIG. 8B except that a first additional charge storing unit terminal 16 is provided which contacts the first charge storing unit terminal 14, the purpose of which is the same as the additional charge storing unit terminal 16 shown in the embodiment C of FIG. 7A.

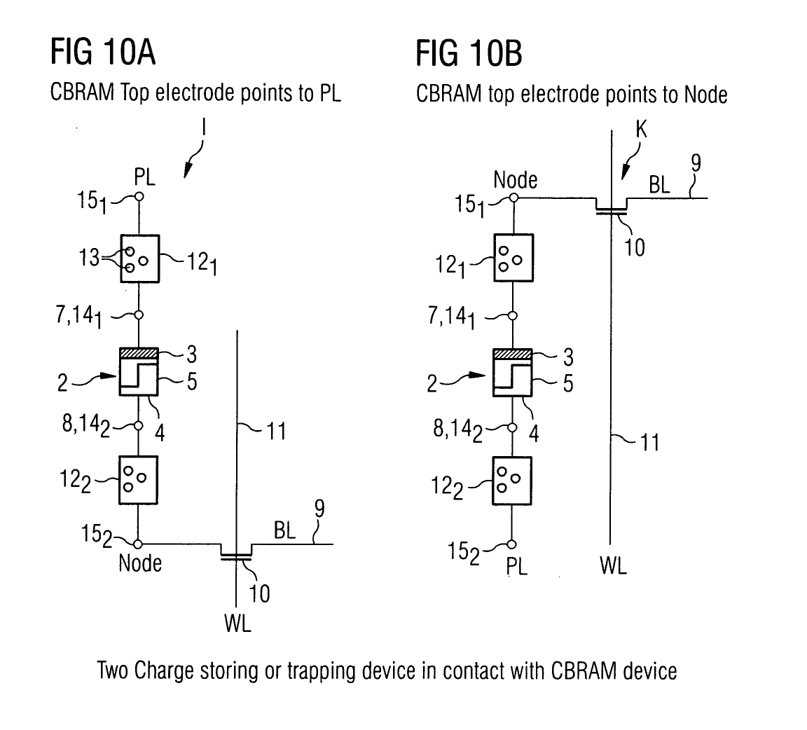

FIG. 10A shows an embodiment I of the CBRAM device according to the present invention. The embodiment I includes a CBRAM cell 2 including a reactive electrode 3, an inert electrode 4, and a solid electrolyte 5 positioned between the reactive electrode 3 and the inert electrode 4, a first charge storing unit 12₁, a second charge storing unit 12₂, and a select device 10. The second charge storing unit terminal 15₁ is connected to an area set to a fixed potential (for example, mass potential). The first charge storing unit terminal 14₁ of the first charge storing unit 12₁ is connected to the first CBRAM cell terminal 7. The second CBRAM cell terminal 8 is connected to the first charge storing unit terminal 14₂ of the second charge storing unit 12₂. The second charge storing unit terminal 15₂ of the second charge storing unit 12₂ is connected to the bit line 9 via the select device 10 (controlled by the word line 11).

FIG. 10B shows an embodiment K of the CBRAM device according to the present invention. The embodiment K includes a first charge storing unit 12₁, a CBRAM cell 2 including a reactive electrode 3, an inert electrode 4, and a solid electrolyte 5 positioned between the reactive electrode 3 and the inert electrode, a second charge storing unit 12₂, and a select device 10. The second charge storing unit terminal 15₂ of the second charge storing unit 12₂ is connected to an area set to a fix potential (for example, mass potential). The first charge storing unit terminal 14₂ of the second charge storing unit 12₂ is connected to the second CBRAM cell terminal 7. The first CBRAM cell terminal 8 is connected to the first charge storing unit terminal 14₁ of the first charge storing unit 12₁. The second charge storing unit terminal 15₁ of the first charge storing unit 12₁ is connected to a bit line 9 via the select device 10 (controlled by the word line 11).

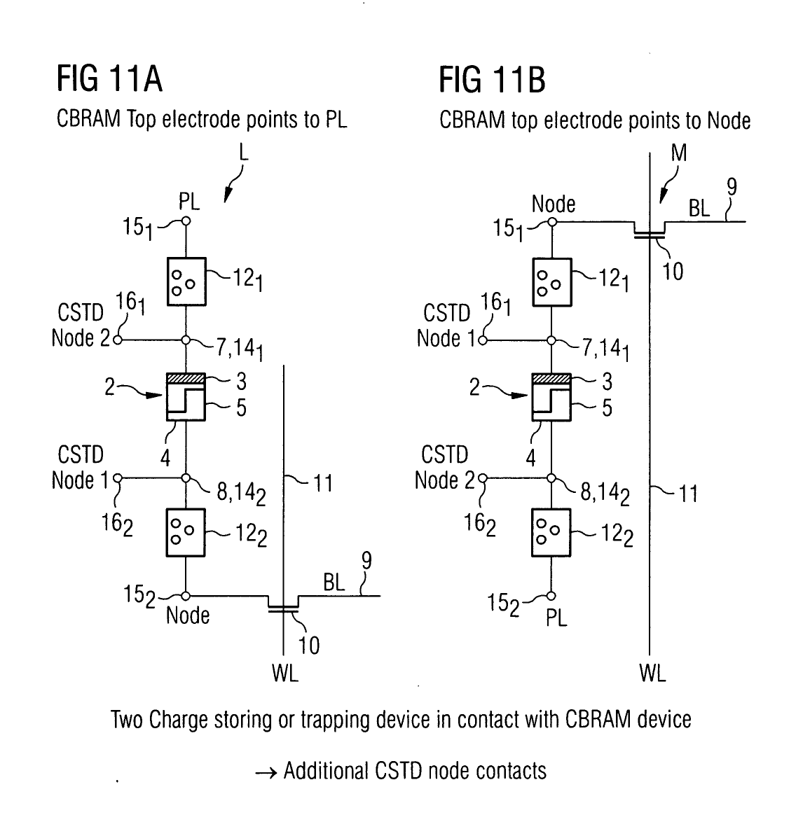

FIG. 11A shows an embodiment L of the CBRAM device according the present invention. The embodiment L has the same architecture as that of the embodiment I shown in FIG. 10A except that a first additional charge storing unit terminal 16₁ connected to the first charge storing unit terminal 14₁ of the first charge storing unit 12₁, and a second additional charge storing unit terminal 16₂ connected to the first charge storing unit terminal 14₂ of the second charge storing unit 12₂ are provided. The purpose of the first and second additional charge storing unit terminals 16₁, 16₂ is the same as that of the additional charge storing unit terminal 16 shown in embodiment C in FIG. 7A.

FIG. 11B shows an embodiment M of the CBRAM device according the present invention. The embodiment M has the same architecture as that of the embodiment K shown in FIG. 10B except that a first additional charge storing unit terminal 16₁ connected to the first charge storing unit terminal 14₁ of the first charge storing unit 12₁, and a second additional charge storing unit terminal 16₂ connected to the first charge storing unit terminal 14₂ of the second charge storing unit 12₂ are provided. The purpose of the first and second additional charge storing unit terminals 16₁, 16₂ is the same as that of the additional charge storing unit terminal 16 shown in embodiment C in FIG. 7A.

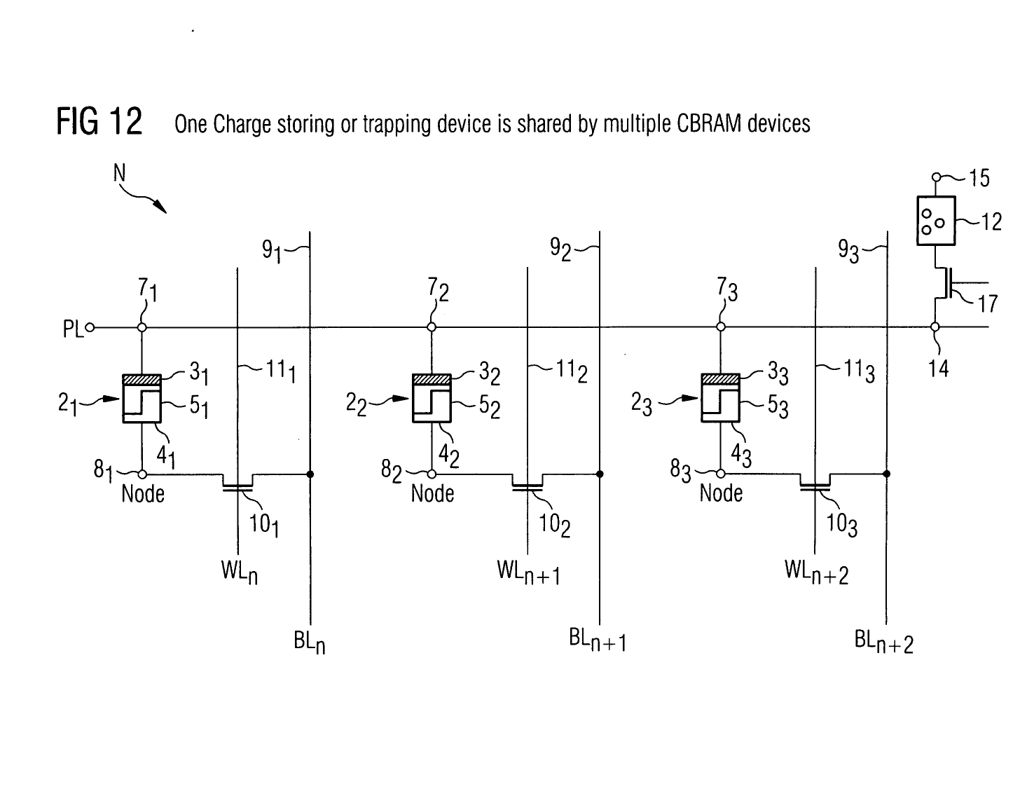

FIG. 12 shows an embodiment N of the CBRAM device according to the present invention. The embodiment N includes a first CBRAM cell 2₁, a second CBRAM cell 2₂, a third CBRAM cell 2₃, a charge storing unit 12, a first select device 10₁, a second select device 10₂, and a third select device 10₃. The first CBRAM cell terminals 7₁ to 7₃ of the first to third CBRAM cells 2₁ to 2₃ are connected to the first charge storing unit terminal 14 of the charge storing unit 12. The first charge storing unit terminal 14 includes a select device 17 in order to connect/disconnect the charge storing unit 12 to the first CBRAM cell terminals 7₁ to 7₃. The second CBRAM cell terminal 8₁ of the first CBRAM cell 2₁ is connected to a first bit line 9₁ via the select device 10₁ controlled by a first word line 11₁. The second CBRAM cell terminal 8₂ of the second CBRAM cell 2₂ is connected to a second bit line 9₂ via the second select device 10₂ controlled by a second word line 11₂. The third CBRAM cell terminal 7₃ of the third CBRAM cell 2₃ is connected to a third bit line 9₃ via the third select device 10₃ controlled by a third word line 11₃.

In this example, one charge storing unit 12 is shared by three CBRAM cells 2, i.e., the charge storing unit 12 simultaneously adjusts writing or erasing volatges for writing or erasing conductive paths within the solid electrolyte 5 of the CBRAM cells 2.

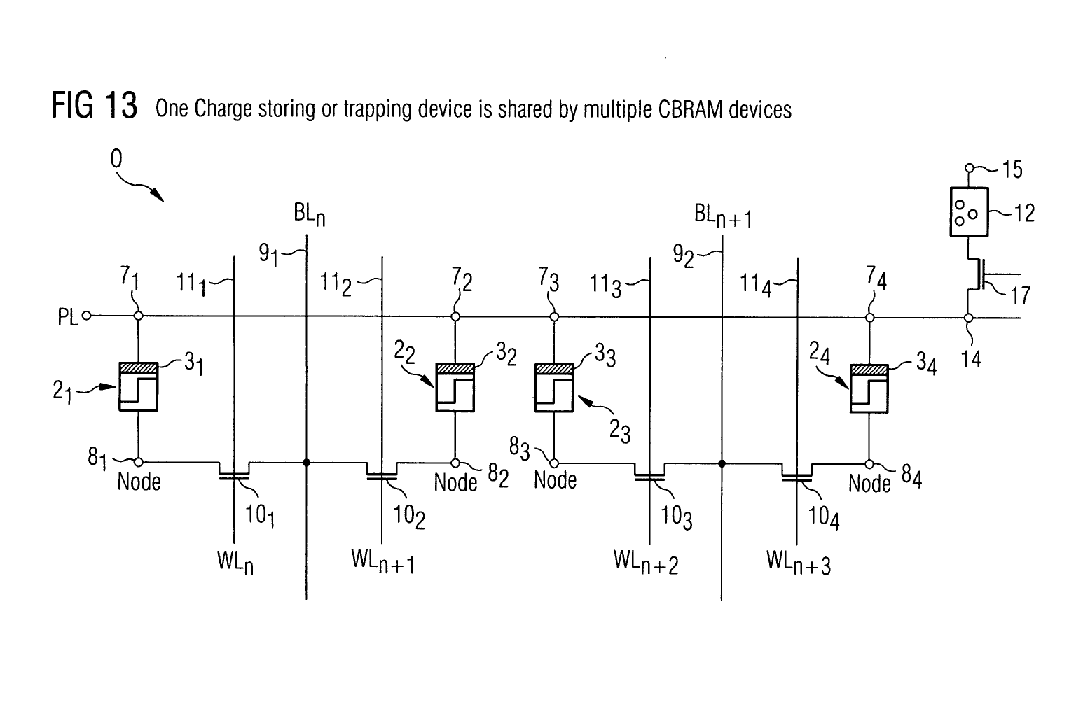

FIG. 13 shows an embodiment O of the CBRAM device according to the present invention. The embodiment O includes a first CBRAM cell 2₁, a second CBRAM cell 2₂, a third CBRAM cell 2₃, a fourth CBRAM cell 2₄, a charge storing unit 12, a first select device 10₁, a second select device 10₂, a third select device 10₃, and a fourth select device 10₄. The first CBRAM cell terminals 7₁ to 7₄ of the first to fourth CBRAM cells 2₁ to 2₄ are connected to the first charge storing unit terminal 14 of the charge storing unit 12. The first charge storing unit terminal 14 includes a select device 17 in order to connect/disconnect the charge storing unit 12 to the first CBRAM cell terminals 7₁ to 7₄. The second CBRAM cell terminal 8₁ of the first CBRAM cell 2₁ is connected to a first bit line 9₁ via the select device 10₁ controlled by a first word line 11₁. The second CBRAM cell terminal 8₂ of the second CBRAM cell 2₂ is connected to the first bit line 9₁ via the second select device 10₂ controlled by a second word line 11₂. The second CBRAM cell terminal 8₃ of the third CBRAM cell 2₃ is connected to a second bit line 9₂ via the third select device 10₃ controlled by a third word line 11₃. The second CBRAM cell terminal 8₄ of the fourth CBRAM cell 2₄ is connected to the second bit line 9₂ via the fourth select device 10₄ controlled by a fourth word line 11₄.

Also in this example, one charge storing unit 12 is shared by three CBRAM cells 2, i.e., the charge storing unit 12 simultaneously adjusts writing or erasing volatges for writing or erasing conductive paths within the solid electrolyte 5 of the CBRAM cells 2.

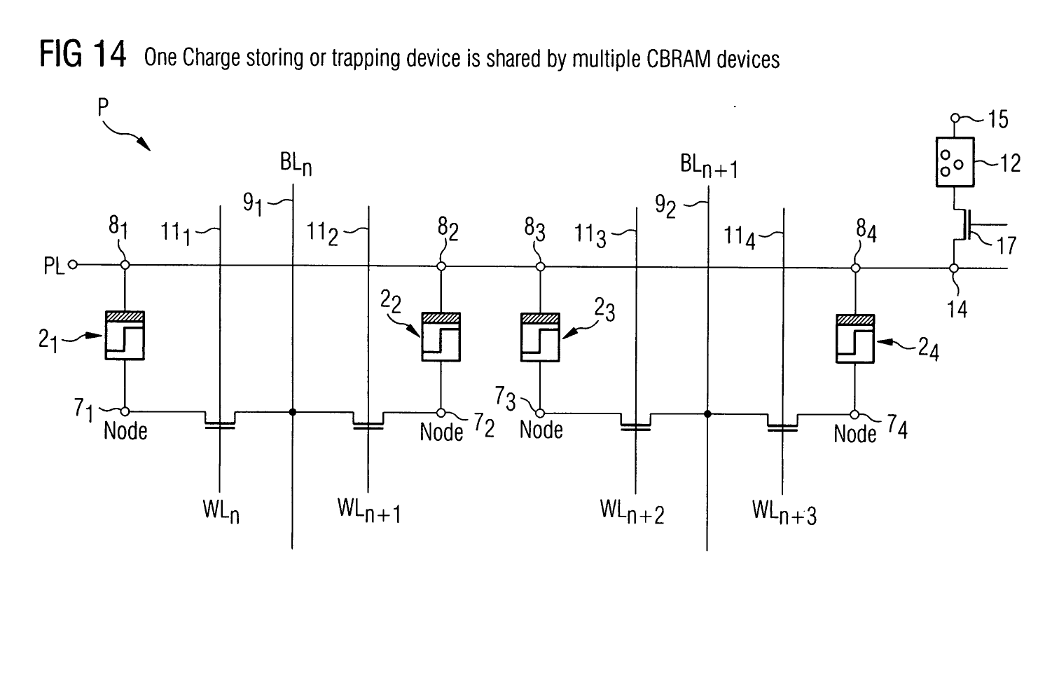

FIG. 14 shows an embodiment P of the CBRAM device according to the present invention. The embodiment P has the same architecture as that of embodiment O shown in FIG. 13 except that the first to fourth CBRAM cells 2₁ to 2₄ are connected inversly into the arrangement.

All embodiments shown in FIGS. 6 to 14 may be stand alone devices or repeating parts of a CBRAM cell array.

In the following description, further aspects of the present invention will be explained.

Conductive bridging cells (CB cells) according to one embodiment include an anode A, an ionic conductor I and a cathode C. The conductivity of the film stack of such a CB cell can be changed so that a non-volatile memory element can be formed. For the detection of the memory state, a read voltage U_{read} is applied, and the current is sensed. For the manufacturing of this memory cell, for example, ionic conductors like Ge—S, Ge—Se, Wox or similar chalcogenide materials are used. The reactive electrodes, for example, comprise copper (Cu) or silver (Ag) or both.

The reactive metallic electrodes provide mobile ions that can penetrate through the chalcogenide matrix by applying an external bias. By changing the pulse duration of the external bias, the amount of metallic ions that are driven into the solid electrolyte can be controlled and even quantitatively calculated using Faraday's law.

During write operation, an external bias is applied (U_{write}>U_{read}), metallic electrode material is oxidized, goes into solution, and gets mobile under the influence of an external electric field. It may be necessary to form a specific nanostructure (“conditioning”) before the device is operating. There are nanodisperse precipitations in the chalcogenide matrix, which are also prone to this electronic redox reaction.

As soon as enough ions have diffused in the direction of the cathode, a conductive bridge is formed between the anode and the cathode so that the electric resistance of the cell is reduced by several orders of magnitude. During the write process, the cathode/electrolyte interface changes since metallic ions are reduced to form a metallic or metal containing deposit.

During the erase process upon applying Uₑᵣₐₛₑ (where, in absolute values Uₑᵣₐₛₑ>V_{t,off}) the metallic ions drift backwards to the reactive electrode and the formerly conductive bridge is dissolved electrolytically. This causes the cell resistance to increase drastically.

Within this context a problem that has not yet been solved is the rather critical erase behavior. Generally, one finds an erase voltage (threshold where the cell switches from on to off) of about −30 to −150 mV. The value is generally very small and the voltage is not very reproducible. This behavior is currently seen to be a major issue to allow reliable cell operation. Bad retention behavior is, therefore, often observed for these cells and an extremely high sensitivity to disturb pulses is very pronounced.

According to one embodiment of the present invention, further semiconductor elements are introduced and connected in series to the CBRAM cell. This gives the opportunity to tune and optimize, as well as to stabilize the switching threshold (on=>off, off=>on) in a reliable way. These parameters can be changed and/or modified either during the operation or directly after fabrication of the chip, so that there is a possibility of forming a volatile as well as a non-volatile memory with a reduced or with an increased data retention capability.

The switching thresholds V_{t,on} and V_{t,off} of an electrolytic memory device are influenced by a variety of parameters. For example, the switching voltage can be influenced by the choice of the inert electrode material. This is caused by the difference in the electrical Fermi level of the reactive electrode and the inert electrode material. Depending on the Fermi level or the work function, one expects the formation of a Schottky barrier-like contact since here, a metal is in direct contact with a semiconducting material (such as Ge—S or Ag₂S, for example). This is also true for the contact between the reactive electrode (e.g., Ag) and the chalcongenide material.

By the existence of such a metal/semiconductor interface there exists also a built-in potential, which can be calculated by the difference of the Fermi levels of the electrode material and the semiconducting material.

$${V}_{bi} = {W}_{{a}^{-}} {Φ}_{HL} = {W}_{{a}^{-}} ( χ + \frac{{E}_{C} - {E}_{F , n}}{q} ) = {W}_{{a}^{-}} χ - \frac{{E}_{C} - {E}_{F , n}}{q}$$

for a metal/n-semiconductor contact

$${V}_{bi} = {Φ}_{HL} - {W}_{a} = ( χ + \frac{{E}_{C} - {E}_{F , p}}{q} ) - {W}_{a}$$

for a metal/p-semiconductor contact
where the symbols denominate the following:

V_{bi}: built-in potential,

Wₐ work function of the metal,

χ electron affinity of the semiconductor,

E_{C} the energy level of the conduction band of the semiconductor

E_{F,p} Fermi level of the p-semiconductor,

E_{F,n} Fermi level of the n-semiconductor,

Φ_{HL} Fermi level of the semiconducting material, and

q elementary charge (1,602×10⁻¹⁹ As).

The combination of two electrode materials, whose work function difference is significant should, therefore, lead to an effective electric field (effective additional built-in voltage) across the cell, which influences the threshold for switching the cell from the on state to the off state and vice versa. For the case of two identical electrodes the built-in voltages cancel out and thus there is only the electrochemical dissociation voltage required.

A significant influence on the switching voltages of a CBRAM cell is observable for materials having a work function that is different from that of Ag [Wₐ(Ag)=4.7 eV], e.g., Pt(5.3 eV), Co(5.0 eV), Ni(4.9 eV), Ru(4.71 eV), Ir(4.6 eV), Rh(4.6 eV), W(4.55 eV), Cu(4.5 eV), Cr(4.4 eV), Mo((4.2 eV), Al(4.2 eV), Ta(4.1 eV), Ti(4.1 eV), Pb(4.0 eV), where CMOS compatible materials are generally preferred, e.g., Cu, W, Al, Ta, Ti, but also silicides and nitrides, or even conductive oxides can be chosen for that purpose.

As a consequence, one would expect the switching voltages in a CBRAM cell as indicated below, the CBRAM cell consisting of a combination of Ag (top electrode) and W (bottom electrode) and Ge—S as a chalcogenide base glass. A static electrolytic dissociation voltage of Ag₂S clusters have to be dissociated for switching.

However, due to the described built-in Schottky effects, one would expect an intrinsic shift for the switching

ΔΦ=Φ(Ag)−Φ(W)=4.7 eV−4.55 eV=0.15 eV=0.15 eV, thus+0.15V shift/offset.

V_{t,on}=V_{t,on(el-chem)}+ΔΦ, and V_{t,off}=V_{t,off(el-chem)}+ΔΦ

### This results in effective switching voltages of

−0.21V+0.15V=−0.06V for switching to the off-state and

0.21V+0.15V=0.36V for switching to the on-state.

These values are however prone to significant changes as soon as Ag is deposited on the inert electrode (e.g., W) to form a Ag—W compound or even to form a continuous layer of Ag. In this case, the physical and chemical properties of the inert electrode (especially the work function) are changed, thus resulting in a change of the built-in voltage over the device. Such a change can be attained by electrolytically depositing Ag over long times (overprogramming) or by atomic Ag diffusion and grain nucleation at the W electrode surface.

According to an embodiment of the present invention, an important aspect is to manipulate the switching threshold of a CBRAM cell by adding a charge storage unit to the CBRAM cell, thereby obtaining a CBC (conductive bridging charge) cell. This avoids the optimization of any material specific parameters or material inherent parameters such as the work function of the electrodes. These additional charge storage or charge trapping units influence the switching voltages of connected CBRAM cells in such a way that the change in Vt (voltage threshold) is directly related (in the most simple case directly proportional) to the amount of stored charge.

As a charge storage or charge trapping unit, a semiconductor or an insulator may be used. Another possibility is to use a combination of a plurality films, which act as a charge storing unit. The charge might even be trapped at an interface. Even an isolated metal dot or metal film can be used to store the charge in the CB cell.

According to one embodiment of the present invention, the charge storing units might include a dielectric material, a semiconducting material, a metallic material, or an appropriate combination of the aforementioned materials to enable a charge storing or charge trapping effect.

According to one embodiment of the present invention, the charge storing units include or consist of an interface (e.g., a metal-semiconductor interface, a semiconductor-insulator interface, a metal-insulator interface or a semiconductor-semiconductor interface) with well defined charge storing and/or trapping properties.

According to one embodiment of the present invention, the charge storing units are implemented on a large amount of memory cells (one charge storing unit is shared between multiple cells).

According to one embodiment of the present invention, the charge storing units are used as an internal reference for erasing and/or programming of the CBRAM cells. In other words, one or more cells may be equipped with a charge storing element. These cells can be used as reference cells in terms of parameters, e.g., Iₒₙ, I_{off}, V_{t,on} and/or V_{t,off}.

According to one embodiment of the present invention, the charge storing units are charged during processing/manufacturing of the chip (fixed charged on charge storing unit).

According to one embodiment of the present invention, the charge storing units are charged during a power up process of a chip comprising the CBRAM device (e.g., via controller, feedback loop, and/or algorithm to store a defined amount of charge on the charge storing units).

According to one embodiment of the present invention, to store charge on the charge storing units, a voltage is applied over the charge storing unit (e.g., using a voltage that is higher or even significantly higher than the voltage commonly used for programming, reading, and erasing the CBRAM devices).

According to one embodiment of the present invention, the charge storing units can be charged and/or discharged during a power up/down process and/or an idle mode of a chip comprising the CBRAM device, the array, the block, the sector, or any part of the CBRAM cells on the full chip.

According to one embodiment of the present invention, the amount of charge on the charge storing units can be controlled by a logic.

According to one embodiment of the present invention, the amount of charge on the charge storing units can be defined by fusing fuses or antifuses on the manufactured chip. Different capacities or circuits are available on the chips for the supply of different charging levels. The amount of charge can be defined by fusing fuses/antifuses.

As used herein the terms connected and coupled are intended to include both direct and indirect connection and coupling, respectively.

In the context of this description chalcogenide material (ion conductor) is to be understood, for example, as any compound containing oxygen, sulphur, selenium, and/or tellurium. In accordance with one embodiment of the invention, the ion conducting material is, for example, a compound, which is made of a chalcogenide and at least one metal of the group I or group II of the periodic system, for example, arsene-trisulfide-silver. Alternatively, the chalcogenide material contains germanium-sulfide (GeS), germanium-selenide (GeSe), tungsten oxide (WOₓ), copper sulfide (CuS) or the like. The ion conducting material may be a solid state electrolyte.

Furthermore, the ion conducting material can be made of a chalcogenide material containing metal ions, wherein the metal ions can be made of a metal, which is selected from a group consisting of silver, copper and zinc or of a combination or an alloy of these metals.

According to one embodiment of the present invention, the reactive electrodes of the CBRAM cells include silver (Ag) or copper (Cu).

According to one embodiment of the present invention, the solid electrolyte of the CBRAM cells includes metal M (e.g., Ag or Cu) doped semiconductor material (e.g., chalcogenide glass (=ChG) having M-Ch precipitates).

According to one embodiment of the present invention, the inert electrodes of the CBRAM cells include nickel (Ni), platinum (Pt), tungsten (W), and the like.

According to one embodiment of the present invention, the metal/semiconductor contact comprises M-Ch precipiations in a high-resistive matrix, wherein the M-X precipitates act as metal ion donor for the ChG matrix.

According to one embodiment of the present invention, a certain amount of metal M can be solved in the inert ChG matrix, thereby forming ChG:M. The amount of metal M solved in the matrix determines the resistance of the cell and thus the memory state.

According to one embodiment of the present invention, for M-Ch/ChG based CBRAM devices, the typical precipitation density d is close to the percolation threshold of the precipates: d(M-Ch)=5 nm, a_{M-CH,M-Ch}=2 nm, a_{M-CH,M-Ch} being the size of metal rich precipitates.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A solid electrolyte memory device, comprising:
at least one solid electrolyte memory cell that includes a reactive electrode, an inert electrode, and a solid electrolyte positioned between the reactive electrode and the inert electrode; and
at least one charge storing unit operable to store an electric charge, the at least one charge storing unit being electrically connected to the at least one solid electrolyte memory cell such that tuning voltages resulting from charge stored in the at least one charge storing unit are applied across the solid electrolyte of each solid electrolyte memory cell connected to the at least one charge storing unit.

2. The solid electrolyte memory device according to claim 1, wherein the amount of charge stored within the at least one charge storing unit is adjustable such that the resulting tuning voltages set erasing voltage thresholds of the at least one solid electrolyte memory cell connected to the at least one charge storing unit to predetermined erasing voltage threshold values.

3. The solid electrolyte memory device according to claim 1, wherein the amount of charge stored within the at least one charge storing unit is adjustable such that the resulting tuning voltages set writing voltage thresholds of the at least one solid electrolyte memory cell connected to the at least one charge storing unit to a predetermined writing voltage threshold values.

4. The solid electrolyte memory device according to claim 1, wherein the amount of charge stored within the at least one charge storing unit ranges from Q=1.602*10⁻¹⁹ As to 1*10⁻¹⁵ As per charge storing unit.

5. The solid electrolyte memory device according to claim 1, wherein each charge storing unit is either connected to the reactive electrode or the inert electrode of the at least one solid electrolyte memory cell.

6. The solid electrolyte memory device according to claim 1, wherein each charge storing unit is serially connected into the sensing current path of the at least one solid electrolyte memory cell.

7. The solid electrolyte memory device according to claim 1, wherein at least one charge storing unit is connected to reactive electrodes of a plurality of solid electrolyte memory cells or to inert electrodes of a plurality of solid electrolyte memory cells.

8. The solid electrolyte memory device according to claim 1, wherein a sensing current path of the at least one solid electrolyte memory cell comprises two charge storing units, a first charge storing unit being connected into a part of the sensing current path connected to the reactive electrode of the at least one solid electrolyte memory cell, and a second charge storing unit being connected into a part of the sensing current path connected to the inert electrode of the at least one solid electrolyte memory cell.

9. The solid electrolyte memory device according to claim 1, wherein the charge stored within the at least one charge storing unit is adjustable by applying a charge storing unit programming voltage across the at least one charge storing unit.

10. The solid electrolyte memory device according to claim 9, wherein the charge storing unit programming voltage is higher than the writing voltage or the erasing voltage necessary for forming or erasing conductive paths within the at least one solid electrolyte memory cell.

11. The solid electrolyte memory device according to claim 9, wherein at least one charge storing unit comprises a current path input terminal and a current path output terminal, the charge of each charge storing unit being adjustable by applying a programming voltage across the charge storing unit using the current path input terminal and the current path output terminal as programming voltage terminals.

12. The solid electrolyte memory device according to claim 1, wherein at least one charge storing unit is arranged such that the tuning voltage generated by the charge storing unit is directly proportional to the charge stored within the charge storing unit.

13. The solid electrolyte memory device according to claim 2, wherein the charge stored within the at least one charge storing unit is adjustable during a power up process, a power down process, or an idle mode of the solid electrolyte memory device or a part thereof.

14. The solid electrolyte memory device according to claim 2, wherein the charge stored within the at least one charge storing unit is adjustable during the operation of the solid electrolyte memory device.

15. The solid electrolyte memory device according to claim 2, wherein the amount of charge stored within the at least one charge storing unit is adjustable during a memory operation performed within the solid electrolyte memory device.

16. The solid electrolyte memory device according to claim 2, wherein the amount of charge stored within the at least one charge storing unit is adjustable during a manufacturing process of the solid electrolyte memory device.

17. The solid electrolyte memory device according to claim 2, further comprising means for controlling the charge amount adjustment process.

18. The solid electrolyte memory device according to claim 2, further comprising a charge adjustment interface connectable to an external controlling means, the amount of charge adjustment process being controllable by an external controller via the charge adjustment interface.

19. The solid electrolyte memory device according to claim 1, wherein the at least one charge storing unit comprises a charge trapping unit.

20. The solid electrolyte memory device according to claim 1, wherein the at least one charge storing unit comprises dielectric material, semiconducting material, metallic material, or a combination of these materials.

21. The solid electrolyte memory device according to claim 1, wherein the at least one charge storing unit comprises a non volatile charge storing element storing electrons or holes in a non-volatile manner.

22. The solid electrolyte memory device according to claim 1, wherein the at least one charge storing unit is charged by trapping or storing electrons or holes.

23. A charge storing unit module comprising at least one charge storing unit storing an electric charge, the at least one charge storing unit being electrically connectable to at least one solid electrolyte memory cell of a solid electrolyte memory device such that tuning voltages resulting from the stored charge are applied across the solid electrolyte of each solid electrolyte memory cell connected to the at least one charge storing unit.

24. The charge storing unit module according to claim 23, wherein the amount of charge stored within the at least one charge storing unit is adjustable such that the resulting tuning voltages set erasing voltage thresholds of the at least one solid electrolyte memory cell connected to the at least one charge storing unit to predetermined erasing voltage threshold values.

25. The charge storing unit module according to claim 23, wherein the amount of charge stored within the at least one charge storing unit is adjustable such that the resulting tuning voltages set writing voltage thresholds of the at least one solid electrolyte memory cell connected to the charge storing unit to predetermined writing voltage threshold values.

26. The charge storing unit module according to claim 23, wherein the amount of charge stored within a charge storing unit ranges from Q=1.602*10⁻¹⁹ As to 1*10⁻¹⁵ As.

27. The charge storing unit module according to claim 23, wherein the at least one charge storing unit is electrically connectable to the at least one solid electrolyte memory cell via an interface that is part of the charge storing unit module or the solid electrolyte memory device, the interface having defined charge storing and/or trapping properties.

28. A method of tuning an erasing voltage threshold of a solid electrolyte memory cell that is electrically connected to at least one charge storing unit, the method comprising:
adjusting an amount of charge stored within the at least one charge storing unit such that a tuning voltage resulting from the stored charge is applied across the solid electrolyte of the solid electrolyte memory cell, wherein the amount of charge stored is adjusted such that the tuning voltage tunes an erasing voltage threshold of the solid electrolyte memory cell to a predetermined erasing voltage threshold value.

29. A method of tuning a writing voltage threshold of a solid electrolyte memory cell that is electrically connected to at least one charge storing unit, the method comprising:
adjusting an amount of charge stored within the at least one charge storing unit such that a tuning voltage resulting from the stored charge is applied across the solid electrolyte of the solid electrolyte memory cell, wherein the amount of charge stored is adjusted such that the tuning voltage tunes a writing voltage threshold of the solid electrolyte memory cell to a predetermined writing voltage threshold value.
